(19) United States
(12) Patent Application Publication
(10) Pub. No.: US 2012/0176143 A1
(43) Pub. Date: Jul. 12, 2012

(54) SAMPLING APPARATUS AND TEST APPARATUS

(75) Inventors: Masayuki KAWABATA, Saitama (JP); Yasuhide KURAMOCHI, Gunma (JP)

(73) Assignee: ADVANTEST CORPORATION, Tokyo (JP)

(21) Appl. No.: 13/177,563

(22) Filed: Jul. 7, 2011

(30) Foreign Application Priority Data
Aug. 31, 2010 (JP) 2010-194148

(51) Int. Cl. G01R 31/00; H03M 1/12

(52) U.S. Cl. 324/555; 341/122

(57) ABSTRACT

A sampling apparatus that converts an analog target signal in which the same waveform repeats into a digital value by sampling the target signal at each of a plurality of phases, and outputs the digital value. The sampling apparatus comprises a designating section that sequentially designates bits in the digital value as target bits, beginning with the most significant bits; a generating section that, for each designated target bit, generates a threshold value for determining a value of the target bit based on a determined value of a bit that is higher-order than the target bit in the digital value at each of the phases; and a converting section that, for each designated target bit, determines the value of the target bit in the digital value at each phase by comparing the target signal to an analog comparison signal corresponding to the threshold value at each phase.

### BACKGROUND

1. Technical Field

The present invention relates to a sampling apparatus and a test apparatus.

2. Related Art

An apparatus is known that samples the waveform of a signal, such as a sampling oscilloscope or a sampling digitizer. An analog section in such an apparatus includes a broad-band track-and-hold circuit and an AD converter. However, in order to perform sampling with higher sampling frequency and better resolution, the sampling apparatus must include a high-speed and high-resolution analog section, for example, which increases the overall circuit size.

Patent Documents 1 and 2 each describe a method for performing an AD conversion, at prescribed phases, on the level of a repeating signal input thereto. More specifically, with this method, the level of the repeating signal at specific phases is AD converted by comparing the repeating signal to a reference signal at a plurality of specified phases of the repeating signal, which are different positions in absolute time. With this method, the AD conversion can be performed with high resolution and high sampling frequency, without including a high-speed and high-resolution analog section and without increasing the circuit size.

Patent Document 1: U.S. Pat. No. 5,578,935

### Patent Document 2: Japanese Patent Application Publication No. 2005-249690

However, in this AD converting method, a long conversion time is required when performing an AD conversion on the level of the repeating signal at a plurality of phases. For example, when M represents the period of the repeating signal, P represents the number of phases at which sampling is performed, and N represents the resolution of the digital value, the total conversion time is at least M×P×N.

### SUMMARY

Therefore, it is an object of an aspect of the innovations herein to provide a sampling apparatus and a test apparatus, which are capable of overcoming the above drawbacks accompanying the related art. The above and other objects can be achieved by combinations described in the independent claims. The dependent claims define further advantageous and exemplary combinations of the innovations herein. According to a first aspect related to the innovations herein, provided is a sampling apparatus that converts an analog target signal in which the same waveform repeats into a digital value by sampling the target signal at each of a plurality of phases, and outputs the digital value. The sampling apparatus comprises a designating section that sequentially designates bits in the digital value as target bits, beginning with the most significant bits; a generating section that, for each designated target bit, generates a threshold value for determining a value of the target bit based on a determined value of a bit that is higher-order than the target bit in the digital value at each of the phases; and a converting section that, for each designated target bit, determines the value of the target bit in the digital value at each phase by comparing the target signal to an analog comparison signal corresponding to the threshold value at each phase. Also provided is a test apparatus comprising the sampling apparatus.

The summary clause does not necessarily describe all necessary features of the embodiments of the present invention. The present invention may also be a sub-combination of the features described above.

### BRIEF DESCRIPTION OF THE DRAWINGS

FIG. 1 shows a configuration of a sampling apparatus 10 according to an embodiment of the present invention.

FIG. 2 shows an exemplary process flow of the sampling apparatus 10 according to the present embodiment.

FIG. 3 shows an exemplary process flow of step S15 shown in FIG. 2.

FIG. 4 shows an exemplary waveform of the target signal along with conversion result and comparison signal in the conversion process for the N-th bit (MSB).

FIG. 5 shows an exemplary waveform of the target signal along with a conversion result and comparison signal in the conversion process for the (N−1)-th bit.

FIG. 6 shows an exemplary waveform of the target signal along with a comparison result and a comparison signal in the conversion process for the first bit (LSB).

FIG. 7 shows an exemplary target signal and exemplary sampling clocks used when the sampling apparatus 10 of the present embodiment samples the waveform of one cycle of the target signal with a conversion period that is equal to a plurality of cycles of the target signal.

FIG. 8 shows a configuration of the sampling apparatus 10 according to a modification of the present embodiment.

FIG. 9 shows examples of candidate values and determined values for the N-th bit (MSB) in the digital value at each phase of the target signal, as converted by the sampling apparatus 10 of the present modification.

FIG. 10 shows a configuration of a test apparatus 60 according to an embodiment of the present invention.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

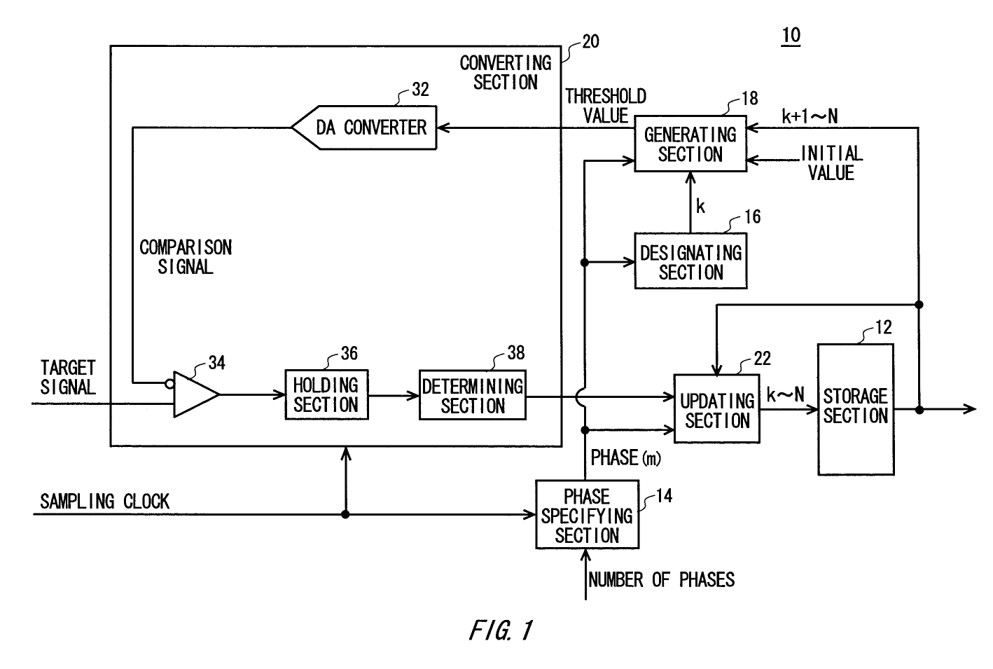

FIG. 1 shows a configuration of a sampling apparatus 10 according to an embodiment of the present invention. The sampling apparatus 10 receives an analog target signal in which the same waveform repeats. The sampling apparatus 10 samples each of a plurality of phases of the target signal, converts the sampling results to digital values, and outputs the digital values.

The sampling apparatus 10 includes a storage section 12, a phase specifying section 14, a designating section 16, a generating section 18, a converting section 20, and an updating section 22. The storage section 12 stores the digital value of each phase in the target signal.

The digital values stored in the storage section 12 have lower accuracy at an initial stage of the conversion, and the accuracy gradually improves as the conversion progresses. For example, among the digital values stored in the storage section 12, the digital value from the initial stage of the conversion has an accuracy of 1-bit data, and each subsequent digital value has data that is 1 bit greater as the conversion progresses. The storage section 12 stores a digital value with a desired accuracy at the final stage of the conversion.

The phase specifying section 14 sequentially specifies phases of the target signal. The phase specifying section 14 may specify a phase of the target signal according to sampling clocks that indicate each phase timing at which the target signal is sampled.

More specifically, the phase specifying section 14 counts the sampling clocks and specifies a phase corresponding to each sampling clock. For example, the phase specifying section 14 may count the sampling clocks such that the count value restarts after each set of a predetermined number of phases. The phase specifying section 14 may output, as a value specifying a phase, the remainder resulting from the count value of the sampling clocks being divided by the predetermined number of phases. As a result, the phase specifying section 14 can specify phases of the target signal at each timing of the sampling clocks.

The designating section 16 sequentially designates a portion of the bits of each digital value as target bits, beginning with the most significant bits. For example, the designating section 16 may sequentially designate one bit at a time, from the most significant bit of a digital value to the least significant bit, to be the target bit. The designating section 16 may update the target bit every time the phase specifying section 14 specifies one cycle of phases in the target signal.

Every time a target bit is designated, the generating section 18 generates, for each phase, a threshold value for determining the value of the target bit in a digital value, based on the value determined for a bit that is higher-order than the target bit in the digital value. For example, the generating section 18 may read from the storage section 12 the values determined for the bits that are higher-order than the target bit in the digital value at the phases specified by the phase specifying section 14, and generate the threshold value for the phases specified by the phase specifying section 14. When the target bit is the most significant bit in the digital value, the generating section 18 may generate a predetermined threshold value, such as an initial value set from an external source.

Every time a target bit is designated, the converting section 20 determines the value of the target bit in the digital value at each phase, by comparing the target signal to an analog comparison signal corresponding to the threshold value at each phase. More specifically, the converting section 20 compares the target signal to the comparison signal at each sampling clock timing. The converting section 20 determines the value of the target bit in the digital value at the phases specified by the phase specifying section 14, based on the comparison result.

The converting section 20 includes a DA converter 32, a comparator 34, a holding section 36, and a determining section 38, for example. The DA converter 32 outputs an analog comparison signal corresponding to the threshold value generated by the generating section 18, for each sampling clock. The comparator 34 compares the level of the target signal to the level of the comparison signal output from the DA converter 32, for each sampling clock. In other words, the comparator 34 outputs a comparison result indicating whether the level of the target signal is greater than the level of the comparison signal.

The holding section 36 temporarily holds the comparison result output from the comparator 34. The determining section 38 determines the value of the target bit in the digital value at the phases specified by the phase specifying section 14, based on the comparison result held by the holding section 36. For example, the determining section 38 may determine the target bit to have a value of 1 when the level of the target signal is greater than the level of the comparison signal, and may determine the target bit to have a value of 0 when the level of the target signal is not greater than the level of the comparison signal. In this way, the converting section 20 can determine the value of the target bit in the digital value of the target signal at the phases specified by the phase specifying section 14.

For each phase, the updating section 22 updates the digital value of the target signal stored in the storage section 12 at the phase specified by the phase specifying section 14, based on the value of the target bit determined by the converting section 20. For example, the updating section 22 may write the digital value based on the value of the target bit and the value of each bit that is higher-order than the target bit to an address in the storage section 12 corresponding to the phase specified by the phase specifying section 14.

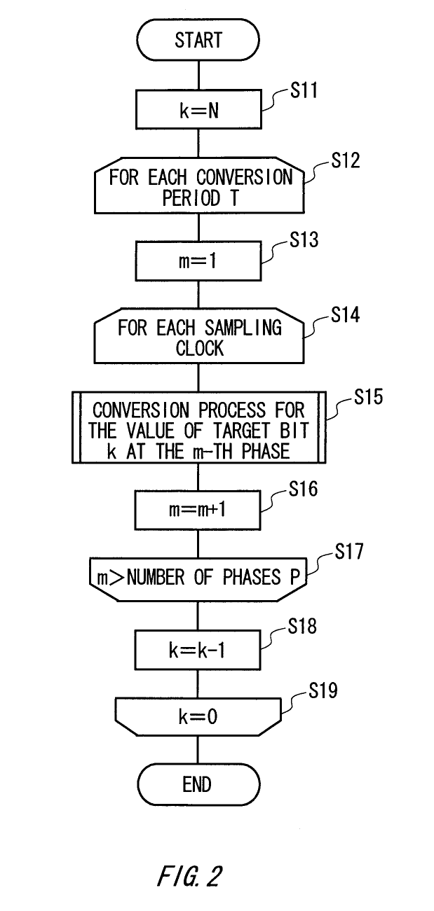

FIG. 2 shows an exemplary process flow of the sampling apparatus 10 according to the present embodiment. In response to receiving a target signal in which the same waveform is repeated, the sampling apparatus 10 performs the processes from step S11 to step S19.

At step S11, the sampling apparatus 10 substitutes N, which is a value representing the resolution and level direction of the sampling apparatus 10, for a variable k that designates the target bit. As a result, the sampling apparatus 10 can designate the N-th bit, which is the most significant bit (MSB), as the target bit.

Next, the sampling apparatus 10 repeatedly performs the processes from step S13 to step S18 for each predetermined conversion period T (the process loop from step S12 to step S19). The length of the conversion period T is L times the period of the target signal, and can be calculated as the product of the period of the sampling clock and the predetermined number of phases P. Here, L and P are coprime natural numbers.

At step S13, the sampling apparatus 10 substitutes the value 1 for the variable m that designates the phase number. As a result, the sampling apparatus 10 can specify the first phase.

Next, the sampling apparatus 10 repeatedly performs the processes of steps S15 and S16 for each sampling clock (the process loop from step S14 to step S17). At step S15, the sampling apparatus 10 performs the conversion process of the value of the target bit k in the digital value of the target signal at the m-th phase of the target signal. The process of step S15 is described in detail further below. At step S16, the sampling apparatus 10 increases the value of the variable m by 1.

If the variable m is greater than the predetermined number of phases P, the sampling apparatus 10 exits the process loop from step S14 to step S17. In this way, the sampling apparatus 10 can determine the value of the target bit in the digital value of the target signal for the entire number of phases P of the target signal.

At step S18, the sampling apparatus 10 decreases the value of the variable k by 1. If the variable k is equal to 0 at step S18, the sampling apparatus 10 exits the process loop from step S12 to step S19 and the process flow is ended. In this way, the sampling apparatus 10 can determine the value of each of the N bits from the most significant bit (MSB) to the least significant bit (LSB) in the digital value, for the entire number of phases P of the target signal.

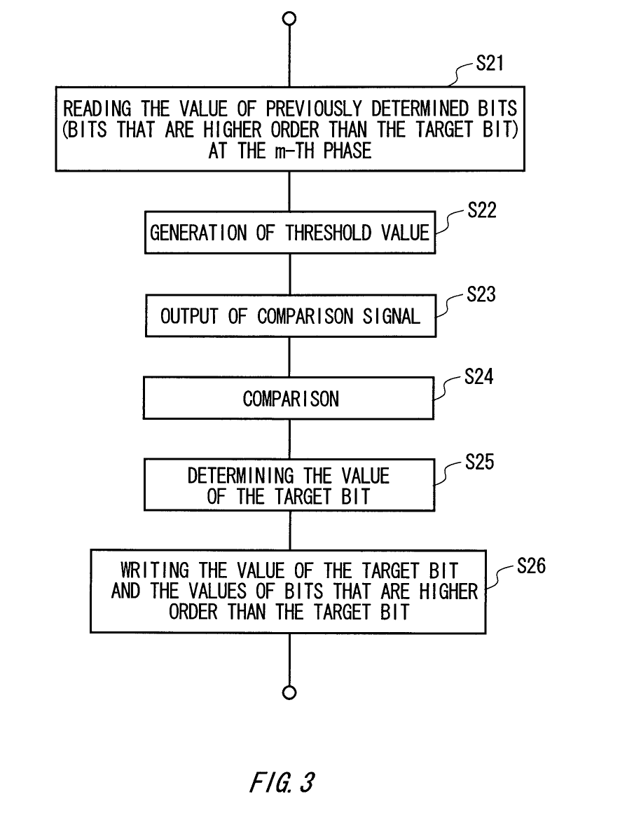

FIG. 3 shows an exemplary process flow of step S15 shown in FIG. 2. At step S15 of FIG. 2, the components of the sampling apparatus 10 perform the processes from step S21 to step S26 described below.

First, at step S21, the generating section 18 reads from the storage section 12 the value of each bit that was already determined at the m-th phase, i.e. the bits that are higher-order than the target bit k. If there is no bit whose value has already been determined, i.e. if the target bit is the most significant bit, the generating section 18 does not read a value from the storage section 12.

Next, at step S22, the generating section 18 generates the threshold value for determining the value of the target bit in the digital value at the m-th phase of the target signal, based on the bit values that were previously determined for the m-th phase of the target signal. The generating section 18 may perform the processes of steps S21 and S22 in advance, prior to the sampling clock that designates the m-th phase.

The generating section 18 may generate the threshold value for determining the value of the target bit according to binary search rules, for example. In other words, the generating section 18 generates the threshold value such that the value of each bit that is higher-order than the target bit is the previously determined value, the value of the target bit is 1, and the value of each bit that is lower-order than the target bit is 0. As a result, the generating section 18 can generate a threshold value for determining whether the value of the target bit in the digital value of the target signal is 0 or 1. If the target bit is the most significant bit in the digital value, the generating section 18 generates a threshold value that results in each bit other than the most significant bit having a value of 0.

At step S23, the DA converter 32 of the converting section 20 performs a DA conversion on the threshold value generated by the generating section 18, and outputs an analog comparison signal corresponding to the threshold value.

At step S24, the comparator 34 of the converting section 20 compares the level of the target signal to the level of the comparison signal. In other words, the comparator 34 outputs a comparison result indicating whether the level of the target signal is greater than the level of the comparison signal.

At step S25, the determining section 38 of the converting section 20 determines the value of the target bit in the digital value at the m-th phase of the target signal, based on the comparison result from the comparator 34. For example, the determining section 38 may determine the target bit to have a value of 1 when the level of the target signal is greater than the level of the comparison signal, and may determine the target bit to have a value of 0 when the level of the target signal is not greater than the level of the comparison signal.

At step S26, the updating section 22 writes to the storage section 12 the value of the target bit determined by the determining section 38 and the values read by the generating section 18 of each bit that is higher-order than the target bit, at the m-th phase. The updating section 22 may write the determined values to the storage section 12 at a timing after the sampling clock that designates the m-th phase.

The sampling apparatus 10 performs the processes from step S21 to step S26 during step S15. In this way, the sampling apparatus 10 can determine the value of the target bit k in the digital value of the target signal at the m-th phase of the target signal, and write this value to the storage section 12.

In the manner described above, the sampling apparatus 10 can sample the waveform of the target signal with a predetermined resolution at a predetermined number of phases. Since the sampling apparatus 10 performs the conversion on only a portion of the bits, e.g. 1 bit, in the digital value for a single sampling clock, a small circuit with low operating frequency can be used to sample the waveform of the target signal with high resolution and high sampling frequency. Furthermore, the sampling apparatus 10 can shorten the time needed to sample the target signal. For example, when S represents the period of the sampling clock, P represents the number of phases, and N represents the resolution of the digital value, the sampling apparatus 10 can finish sampling in a time equal to S×P×N.

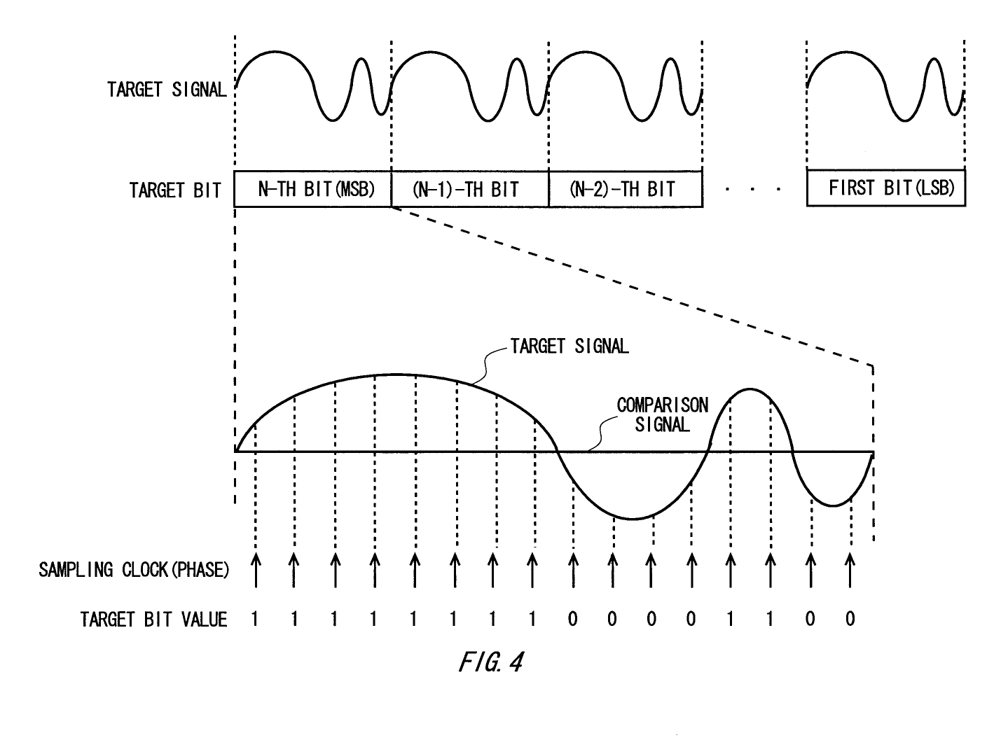

FIG. 4 shows an exemplary waveform of the target signal along with conversion result and comparison signal in the conversion process for the N-th bit (MSB). In the first conversion period, the sampling apparatus 10 determines the value of the N-th bit (MSB) for each phase of the target signal.

When converting the value of the N-th bit, the sampling apparatus 10 generates the threshold value to be a predetermined initial value, e.g. a value that is half the maximum value of the digital value, for every phase. Accordingly, when determining the value of the N-th bit, the sampling apparatus 10 outputs a comparison signal with the same level for all of the phases.

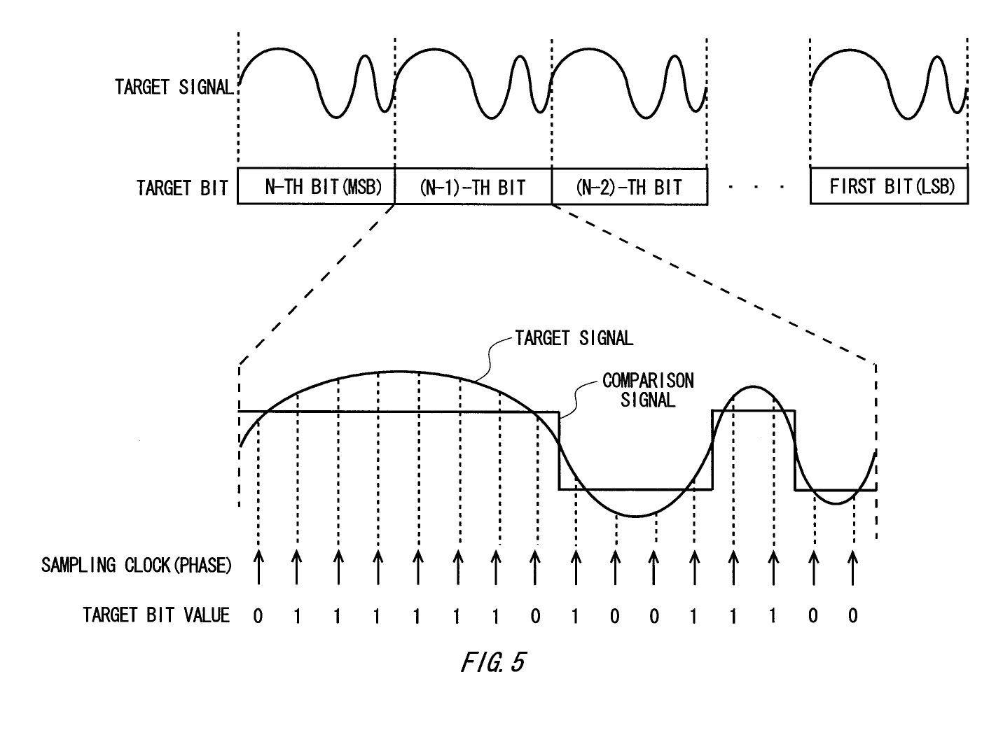

FIG. 5 shows an exemplary waveform of the target signal along with a conversion result and comparison signal in the conversion process for the (N−1)-th bit. In the conversion period following the conversion period of the N-th bit, the sampling apparatus 10 determines the value of the (N−1)-th bit for each phase of the target signal.

When converting the value of the (N−1)-th bit, the sampling apparatus 10 generates the threshold value based on the determined values, i.e. the value of the N-th bit, for every phase. Accordingly, when determining the value of the (N−1)-th bit, the sampling apparatus 10 outputs a comparison signal with a different level for each of the phases.

For the bits lower than the (N−1)-th bit, the sampling apparatus 10 generates the threshold value based on the determined values for every phase, in the same manner as described above. Accordingly, when determining the values of bits lower than the (N−1)-th bit, the sampling apparatus 10 outputs a comparison signal with a different level for each of the phases.

Here, the accuracy of the determined digital value increases one bit at a time as the conversion periods progress. In other words, the determined value has a 1-bit accuracy after the conversion period of the N-th bit is finished, has a 2-bit accuracy after the conversion period of the (N−1)-th bit is finished, and has a (X+1)-bit accuracy after the conversion period of the (N−X)-th bit is finished.

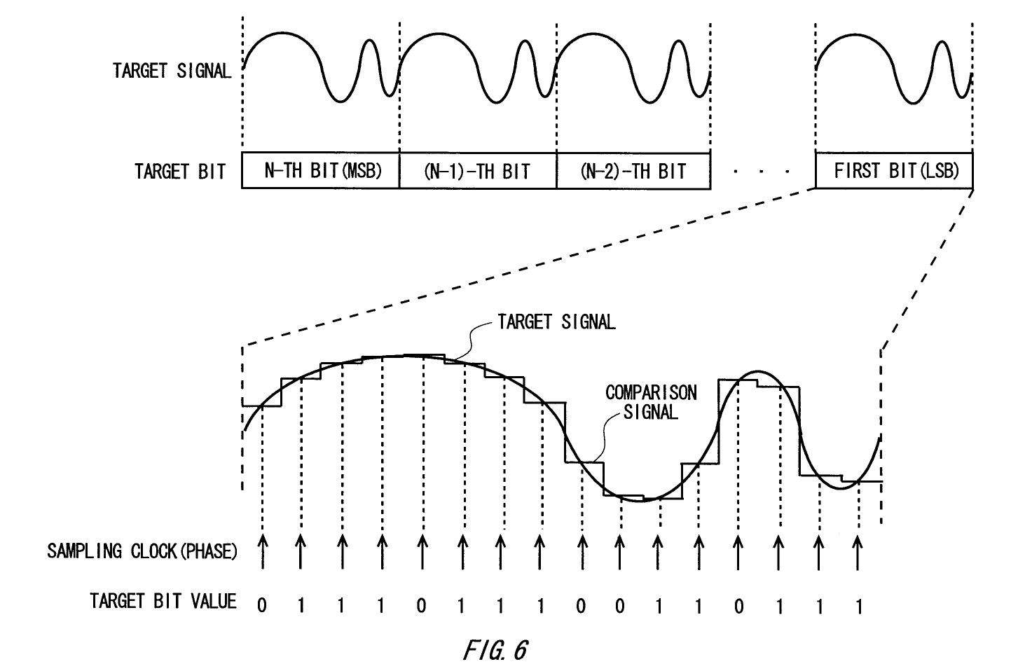

FIG. 6 shows an exemplary waveform of the target signal along with a comparison result and a comparison signal in the conversion process for the first bit (LSB). In the conversion period for the first bit, i.e. the final conversion period, the sampling apparatus 10 determines the value of the first bit for each phase of the target signal.

When converting the value of the first bit, the sampling apparatus 10 generates the threshold value based on the determined values, i.e. the value of each bit from the N-th bit to the second bit, for every phase. In this case, the determined values have already been converted with a high degree of accuracy. Accordingly, the sampling apparatus 10 outputs a comparison signal with a waveform similar to that of the target signal.

In this way, the sampling apparatus 10 determines the digital value at each phase of the target signal is sequentially, e.g. one bit at a time, from the most significant bit to the least significant bit. Accordingly, the sampling apparatus 10 can sequentially update the digital value stored in the storage section 12 and gradually increase the accuracy as time passes.

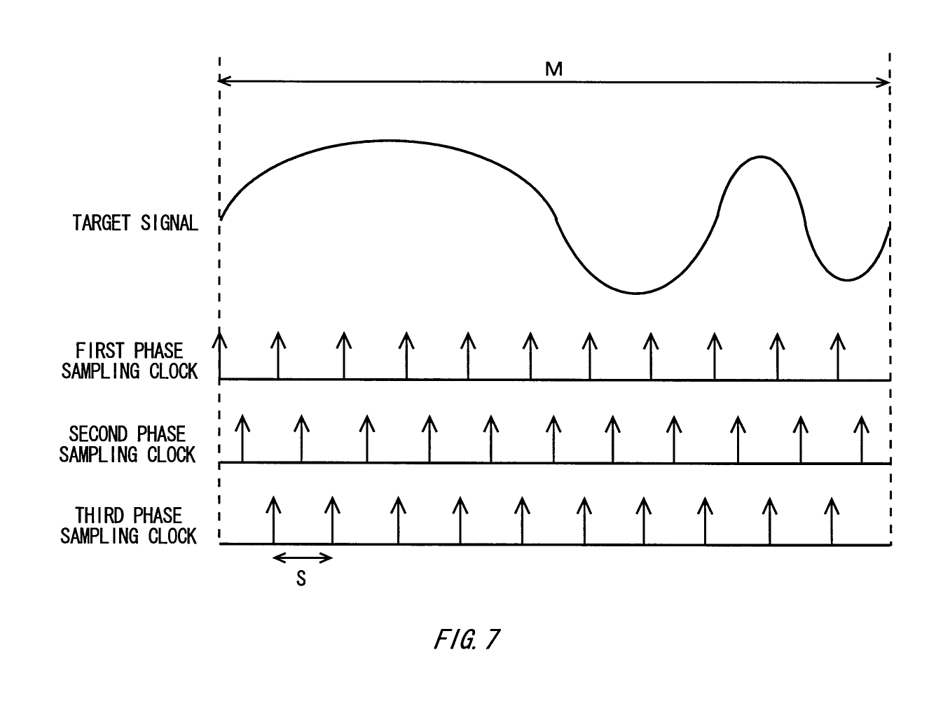

FIG. 7 shows an exemplary target signal and exemplary sampling clocks used when the sampling apparatus 10 of the present embodiment samples the waveform of one cycle of the target signal with a conversion period that is equal to a plurality of cycles of the target signal. The sampling apparatus 10 may sample the waveform of one cycle of the target signal with a conversion period equal to a plurality of cycles of the target signal. For example, as shown in FIG. 7, the sampling apparatus 10 may sample the waveform of one cycle of the target signal with a conversion period equal to a three cycles of the target signal.

Here, M represents the period of the waveform of the target signal, S represents the period of the sampling clock, P represents the number of phases at which the waveform of the target signal is sampled by the sampling apparatus 10, and L represents the number of waveforms (cycles) of the target signal included in one conversion period. In this case, the sampling apparatus 10 samples the waveform of the target signal such that the relationship of Expression 1 shown below is established. Here, L and P are natural numbers that are coprime.

M×L=S×P Expression 1

In this way, the sampling apparatus 10 can sample the waveform of the target signal with a period shorter than the period S of the sampling clock by sampling a first waveform of the target signal over a plurality of cycles of the target signal.

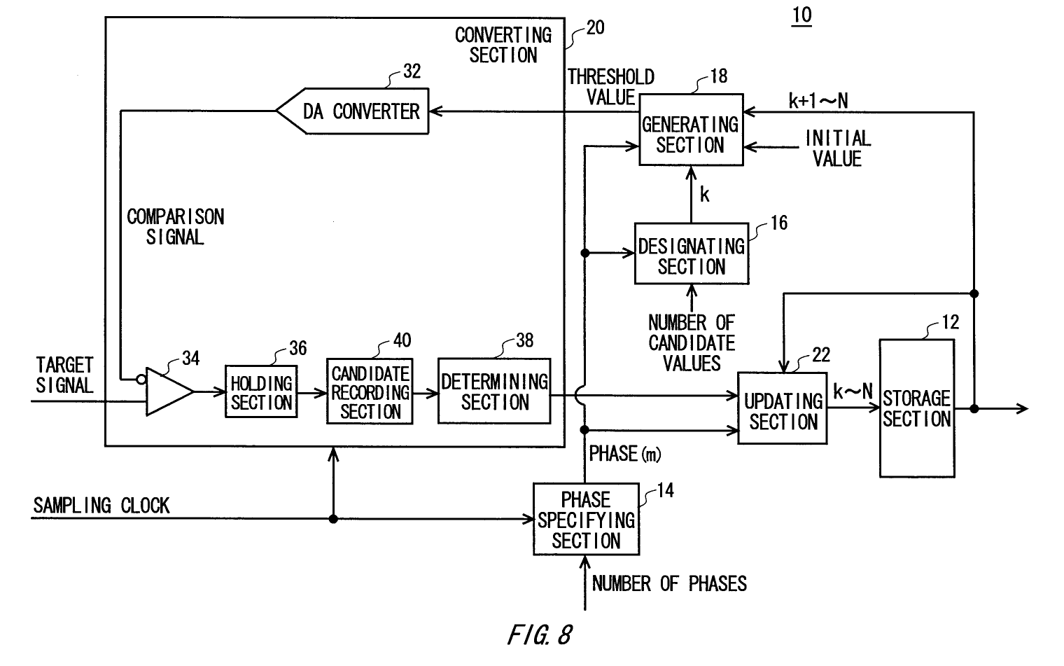

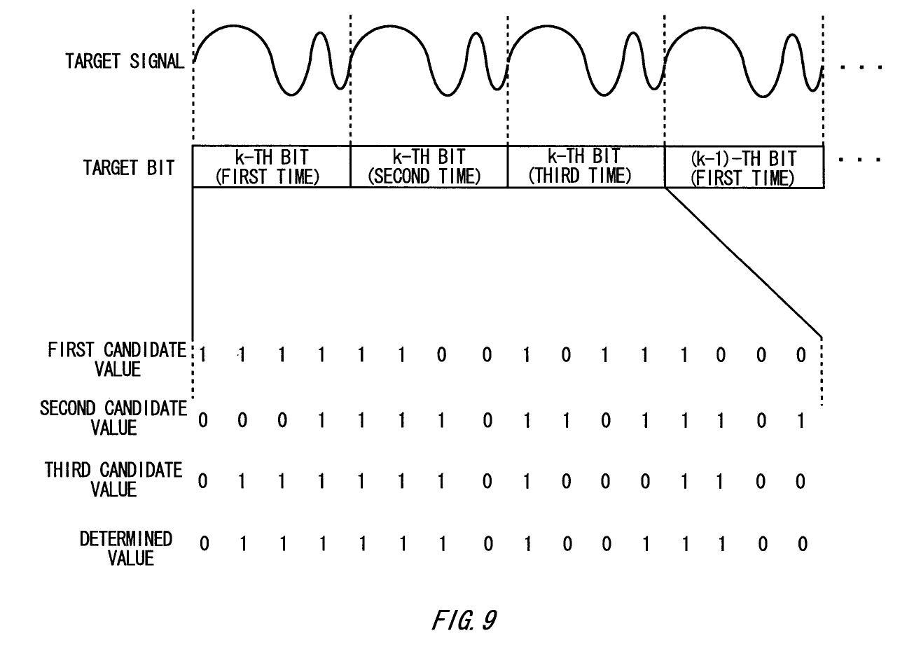

FIG. 8 shows a configuration of the sampling apparatus 10 according to a modification of the present embodiment. FIG. 9 shows examples of candidate values and determined values for the N-th bit (MSB) in the digital value at each phase of the target signal, as converted by the sampling apparatus 10 of the present modification. The sampling apparatus 10 of the present modification adopts substantially the same function and configuration as the sampling apparatus 10 shown in FIG. 1, and therefore components having substantially the same function and configuration as those of the sampling apparatus 10 shown in FIG. 1 are given the same reference numerals and further description is omitted.

The number of candidate values used for determining the value of the target bit is set in the designating section 16 of the present modification from the outside. For example, an odd and natural number may be set as the number of candidate values in the designating section 16 from the outside. The designating section 16 updates the target bit every time the phase specifying section 14 specifies phases of a number of cycles equal to the number of candidate values in the target signal. For example, when 3 is set as the number of candidate values, the designating section 16 may update the target bit every time 3 cycles of phases are specified by the phase specifying section 14.

The converting section 20 compares the comparison signal to the target signal at each of the phases for each target bit, and acquires a plurality of candidate values for the target bit at each phase. The converting section 20 sets the target bit value based on the candidate values at each phase, for each target bit.

The converting section 20 may further include a candidate storage section 40. The candidate storage section 40 records the plurality of candidate values of the target bit at each phase, for each target bit.

For each target bit, the determining section 38 sets the value of the target bit based on the recorded values in the candidate storage section 40 for each of the phases. For example, when a predetermined number, e.g. and odd number, of candidate values are acquired at each phase, the determining section 38 may determine the value of the target bit based on the majority value among the candidate values. As another example, the determining section 38 may calculate the average value of the candidate values, and determine the value of the target bit by making a magnitude comparison between the average value and a predetermined value.

In this way, the converting section 20 of the present modification can accurately determine the value of each target bit. Accordingly, the sampling apparatus 10 of the present modification can accurately sample the waveform of the target signal.

When a reference bit is designated in advance from among the bits of the digital value, the converting section 20 of the present modification may determine the value of the target bit based on more candidate values when the target bit is lower-order than the reference bit than when the target bit is the reference bit. In this way, the converting section 20 of the present modification can more accurately determine the values of lower-order bits, which are more affected by noise.

As another modification, the sampling apparatus 10 may determine the value of each target bit by comparing the target signal to a comparison signal based on redundant threshold values. In other words, for each target bit, the converting section 20 may compare the target signal to the comparison signal at each phase, and determine the value of the target bit and bits that are higher-order than the target bit at each phase.

For example, the converting section 20 may include a plurality of DA converters 32 and a plurality of comparators 34, and may determine the value of the target bit and also check the determined value of the bit whose order is 1 bit higher than the target bit. In this way, even if there if an error in the value of a bit that is higher-order than the target bit, the converting section 20 can correct the incorrect value.

As yet another modification, the sampling apparatus 10 may receive, along with the target signal, a start signal in synchronization with the target signal. In this case, the designating section 16 begins operating in response to receiving the start signal from an external source. As a result, the sampling apparatus 10 can sample the signal output from a device that outputs a signal along with a synchronization signal, for example.

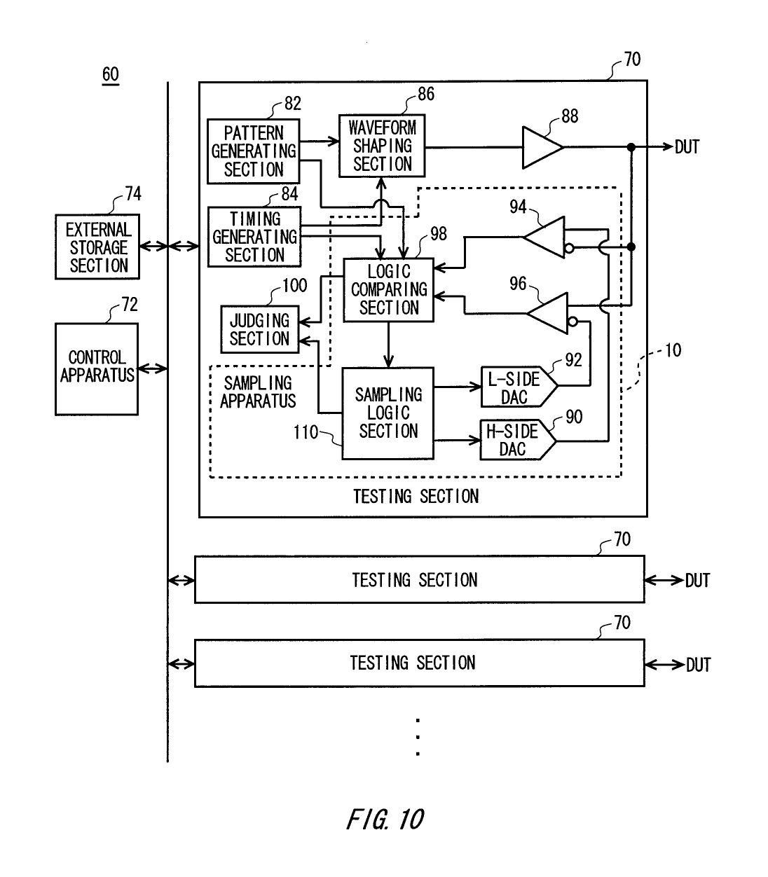

FIG. 10 shows a configuration of a test apparatus 60 according to an embodiment of the present invention. The test apparatus 60 of the present embodiment tests a device under test (DUT).

The test apparatus 60 includes a plurality of testing sections 70, a control apparatus 72, and an external storage section 74. Each testing section 70 supplies a test signal to the device under test. Each testing section 70 receives a response signal output from the device under test in response to the test signal supplied thereto, and judges pass/fail of the device under test by comparing the value of the acquired response signal to an expected value. Each testing section 70 also samples the response signal output from the device under test, and outputs the result as a converted digital value.

The control apparatus 72 is connected to each of the testing sections 70 by a bus, for example, and controls the operation of each testing section 70. The external storage section 74 is connected to each testing section 70 by a bus, for example, and records therein test results received from the testing sections 70. The external storage section 74 also stores therein the waveform data of the response signals acquired by the testing sections 70.

In the test apparatus 60, each testing section 70 has substantially the same configuration. Each testing section 70 may include a pattern generating section 82, a timing generating section 84, a waveform shaping section 86, a driver 88, an H-side DAC 90, an L-side DAC 92, an H-side comparator 94, an L-side comparator 96, a logic comparing section 98, a judging section 100 and a sampling logic section 110.

The pattern generating section 82 outputs a test pattern that designates the waveform of the test signal and an expected value pattern for the response signal to be output from the device under test. The timing generating section 84 outputs a timing signal that indicates the edge timing of the test signal and a strobe signal that indicates the comparison timing between the response signal and the expected value.

The waveform shaping section 86 receives the timing signal and the test pattern, and generates the test signal with the waveform designated by the test pattern. The driver 88 supplies the device under test with the test signal output from the waveform shaping section 86. In this way, the testing section 70 can supply the device under test with the test signal having a waveform according to the test pattern.

The H-side DAC 90 outputs an H-side comparison level for judging whether the level of the response signal is a logic H level. The L-side DAC 92 outputs an L-side comparison level for judging whether the level of the response signal is a logic L level.

The H-side comparator 94 determines whether the level of the response signal output from the device under test is greater than the H-side comparison level. The L-side comparator 96 determines whether the level of the response signal output from the device under test is less than the L-side comparison level.

The logic comparing section 98 acquires the comparison results of the H-side comparator 94 and the L-side comparator 96 at the timing of the strobe signal. The judging section 100 compares the comparison results of the logic comparing section 98 to the expected values. The judging section 100 judges pass/fail of the device under test based on the results of the comparison between the logic value of the response signal and the expected value.

The sampling logic section 110 includes the storage section 12, the phase specifying section 14, the designating section 16, the generating section 18, the updating section 22, the holding section 36, and the determining section 38 shown in FIG. 1. In the test apparatus 60, the sampling logic section 110 works together with at least one of the H-side DAC 90 and the L-side DAC 92, at least one of the H-side comparator 94 and the L-side comparator 96, and the logic comparing section 98 in order to function as the sampling apparatus 10 according to the embodiment described in relation to FIGS. 1 to 9. The test apparatus 60 can realize the portion of the circuit for logic testing and the portion of the circuit for sampling the waveform of the response signal with a single device.

The test apparatus 60 can judge pass/fail of the device under test by judging whether the logic value of the response signal output from the device under test matches the expected value.

The test apparatus 60 outputs the test signal to the device under test, thereby causing the device under test to output a response signal in which the same waveform repeats, and samples the waveform of the response signal using the sampling apparatus 10, which includes function blocks of the sampling logic section 110, at least one of the H-side DAC 90 and the L-side DAC 92, at least one of the H-side comparator 94 and the L-side comparator 96, and the logic comparing section 98. The judging section 100 judges pass/fail of the device under test by comparing the waveform of the response signal sampled by the sampling apparatus 10 to the expected waveform. The test apparatus 60 can judge pass/fail of the device under test by judging whether the waveform of the response signal output from the device under test matches the expected waveform.

The judging section 100 may judge pass/fail of the device under test in response to the sampling apparatus 10 having acquired values for the number of bits up to a reference bit, which is less than the number of bits in the digital value. In this case, the judging section 100 stops the sampling of the response signal by the sampling apparatus 10 when it is judged that the device under test is a fail, and continues the sampling of the response signal by the judging section 100 when the device under test is judged to be a pass. In this way, the test apparatus 60 can eliminate the time used to sample the waveform of the response signal when the device under test has already been judged a fail, thereby decreasing the overall testing time.

When the test apparatus 60 performs the process for sampling the waveform of the response signal output from the device under test a plurality of times, every time one sampling of the response signal is finished, the control apparatus 72 reads the digital value of the waveform of the response signal from the storage section 12 in the sampling apparatus 10 and transmits this digital value to the external storage section 74. The external storage section 74 stores the digital values of the waveform of the response signal that have already been sampled. In this way, the testing section 70 can decrease the amount of space needed in the storage section 12 of the sampling apparatus 10.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A sampling apparatus that converts an analog target signal in which the same waveform repeats into a digital value by sampling the target signal at each of a plurality of phases, and outputs the digital value, the sampling apparatus comprising:
a designating section that sequentially designates bits in the digital value as target bits, beginning with the most significant bits;
a generating section that, for each designated target bit, generates a threshold value for determining a value of the target bit based on a determined value of a bit that is higher-order than the target bit in the digital value at each of the phases; and
a converting section that, for each designated target bit, determines the value of the target bit in the digital value at each phase by comparing the target signal to an analog comparison signal corresponding to the threshold value at each phase.

2. The sampling apparatus according to claim 1, further comprising:
a storage section that stores the digital value at each phase of the target signal; and
an updating section that updates the digital values stored in the storage section based on the target bit value determined for each phase.

3. The sampling apparatus according to claim 2, further comprising a phase specifying section that specifies phases of the target signal, wherein
the designating section updates the target bit every time the phase specifying section designates one cycle of phases in the target signal.

4. The sampling apparatus according to claim 3, wherein
the generating section generates the threshold value at each phase specified by the phase specifying section,
the converting section determines the value of the target bit of the digital value at each phase specified by the phase specifying section, and
the updating section updates the digital values stored in the storage section for each phase specified by the phase specifying section.

5. The sampling apparatus according to claim 4, wherein
the generating section reads from the storage section values that have been previously determined for bits that are higher-order than the target bit at each phase specified by the phase specifying section, and generates the threshold values.

6. The sampling apparatus according to claim 5, wherein
the generating section generates a predetermined threshold value when the target bit is a most significant bit in the digital value.

7. The sampling apparatus according to claim 4, wherein
the updating section writes digital values based on the value of the target bit and the value of each bit that is higher order than the target bit, to addresses in the storage section corresponding respectively to the phases specified by the phase specifying section.

8. The sampling apparatus according to claim 3, wherein
the phase specifying section counts sampling clocks indicating timings of phases and specifies a phase corresponding to each sampling clock.

9. The sampling apparatus according to claim 3, wherein
the designating section updates the target bit for every cycle equal to a natural number multiple of the repeating period of the target signal.

10. The sampling apparatus according to claim 1, wherein the converting section includes:
a DA converter that outputs an analog comparison signal corresponding to the threshold value, for each sampling clock indicating the timing of a phase; and
a comparator that compares a level of the target signal to a level of the comparison signal, for each sampling clock.

11. The sampling apparatus according to claim 1, wherein
for each target bit, the converting section compares the target signal to the comparison signal a plurality of times at each phase to acquire a plurality of candidate values for the value of the target bit at each phase, and determines the value of the target bit based on the candidate values.

12. The sampling apparatus according to claim 11, wherein
the converting section determines the value of the target bit based on more candidate values when the target bit is lower-order than a reference bit than when the target bit is the reference bit.

13. The sampling apparatus according to claim 1, wherein
the designating section starts a conversion operation in response to receiving a start signal from outside.

14. The sampling apparatus according to claim 1, wherein
for each target bit, the converting section compares the target signal to the comparison signal at each phase and determines the value of the target bit and the value of each bit that is higher order than the target bit at each phase.

15. A test apparatus that tests a device under test, comprising one or more testing sections that each cause the device under test to output a response signal in which the same waveform repeats by outputting a test signal to the device under test, where each of the one or more testing sections includes:
the sampling apparatus according to claim 1 that samples the waveform of the response signal; and
a judging section that judges pass/fail of the device under test based on the sampled waveform of the response signal.

16. The test apparatus according to claim 15, wherein
the judging section judges pass/fail of the device under test in response to the sampling apparatus acquiring values for the number of bits up to a reference bit, which is less than the number of bits in the digital value,
the judging section stops the sampling of the response signal by the sampling apparatus when the device under test is judged to be a fail, and
the judging section continues sampling the sampling of the response signal by the sampling apparatus when the device under test is judged to be a pass.

17. The test apparatus according to claim 15, wherein the test apparatus includes:
an external storage section that stores digital values of the waveform of the response signal that have been sampled; and
a control apparatus that, every time the sampling of one response signal is finished, reads the digital values of the waveform of the response signal from the storage section in the sampling apparatus and transmits the read digital values to the external storage section.
